(19) United States
(12) Patent Application Publication
(10) Pub. No.: US 2023/0232608 A1
(43) Pub. Date: Jul. 20, 2023

(54) EPITAXIAL WAFER, METHOD OF MANUFACTURING THE EPITAXIAL WAFER, AND METHOD OF MANUFACTURING A SEMICONDUCTOR DEVICE USING THE EPITAXIAL WAFER

(71) Applicant: INDUSTRY-ACADEMIC COOPERTION FOUNDATION YONSEI UNIVERSITY, Seoul (KR)

(72) Inventors: Dae Hong KO, Goyang-si (KR); Dong Chan SEO, Seoul (KR); Choong Hee CHO, Seoul (KR); Ki Seok LEE, Seoul (KR)

(21) Appl. No.: 18/059,311

(22) Filed: Nov. 28, 2022

(30) Foreign Application Priority Data
Nov. 26, 2021 (KR) 10-2021-0165619
May 27, 2022 (KR) 10-2022-0065411
Nov. 24, 2022 (KR) 10-2022-0158899

(51) Int. Cl. H10B 12/00; H01L 21/02; H01L 21/306; H01L 21/3065

(52) U.S. Cl. CPC H10B 12/05; H01L 21/0245; H01L 21/02532; H01L 21/02576; H01L 21/02579; H01L 21/0262; H01L 21/30604; H01L 21/3065; H01L 21/02381

(57) ABSTRACT

[summary]

An epitaxial wafer is disclosed. The epitaxial wafer includes a substrate; and a stack disposed on the substrate, wherein the stack includes silicon (Si) layers and silicon germanium (SiGe) layers alternately stacked on top of each other, wherein the silicon germanium layer is doped with boron (B) or phosphorus (P).

### TECHNICAL FIELD

The present disclosure relates to an epitaxial wafer used for manufacturing a semiconductor device, a method for manufacturing the same, and a method for manufacturing a semiconductor device using the same.

### BACKGROUND ART OF THE INVENTION

Recently, demand to improve integration of each of a memory device and a non-memory device is increasing. Accordingly, scale down for increasing the integration is continuously researched. A 3D-device implemented in various ways are proposed as an approach to increase the integration of the device.

In response to this trend, researches are being conducted to manufacture a 3D-DRAM device. The 3D-DRAM device has a structure in which DRAM devices are manufactured in a three-dimensional space and are stacked in a Z-axis direction. However, in the three-dimensional stack structure, components of layers are different from each other and thus stress is generated due to a difference between lattice parameters of the layers. As a result, there is a problem in that dislocation between constituent atoms of a crystal lattice may occur and thus defects such as voids and hillocks may occur.

### DESCRIPTION

### Challenge to Solve

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

One purpose of the present disclosure is to provide a method for manufacturing an epitaxial wafer in which a difference between lattice parameters of a Si layer and a Si—Ge layer in a multilayer structure in which the Si layers and the Si—Ge layers are alternately stacked with each other, thereby reducing the defects that may occur therebetween.

Another purpose of the present disclosure is to provide an epitaxial wafer manufactured by the manufacturing method.

Still another purpose of the present disclosure is to provide a method for manufacturing a semiconductor device using the epitaxial wafer.

### Solution to the Problem

A first aspect of the present disclosure provides an epitaxial wafer comprising: a substrate; and a stack disposed on the substrate, wherein the stack includes silicon (Si) layers and silicon germanium (SiGe) layers alternately stacked on top of each other, wherein the silicon germanium layer is doped with boron (B) or phosphorus (P).

In one implementation of the first aspect, the silicon germanium layer includes one selected from a group consisting of compounds respectively represented by following Chemical Formulas 1 to 3:

Si_{1-x-y}GeₓB_{y} (0<x≤0.4, 0<y<0.4) [Chemical Formula 1]

Si_{1-x-y-z}GeₓB_{y}P_{z} (0<x≤0.4, 0<y≤0.4, 0<z≤0.4) [Chemical Formula 2]

Si_{1-x-y}GeₓP_{y} (0<x<0.4, 0<y≤0.4). [Chemical Formula 3]

In one implementation of the first aspect, the silicon germanium layer includes the compound represented by the Chemical Formula 1, wherein in the Chemical Formula 1, a ratio (y/x) of y to xis in a range of 0.06 to 0.15.

In one implementation of the first aspect, the silicon germanium layer includes the compound represented by the Chemical Formula 2, wherein in the Chemical Formula 2, a ratio (y/x) of y to x is in a range of 0.06 to 0.15, and y is greater than or equal to z.

In one implementation of the first aspect, 2, wherein the silicon germanium layer includes the compound represented by the Chemical Formula 3, wherein in the Chemical Formula 3, a ratio (y/x) of y to xis in a range of 0.06 to 0.15.

In one implementation of the first aspect, 2, wherein an average thickness of each of the silicon layer and the silicon germanium layer is in a range of 0 nm exclusive to 200 nm inclusive.

A second aspect of the present disclosure provides aa method for manufacturing an epitaxial wafer, the method comprising: performing a cycle composed of a first step and a second step a plurality of times to form a stack on a substrate, wherein the stack includes a plurality of silicon layers and a plurality of silicon germanium layers alternately stacked on top of each other, wherein the first step includes forming one of the silicon layer and the silicon germanium layer on the substrate, wherein the silicon germanium layer is doped with boron (B) or phosphorus (P), wherein the second step includes epitaxially forming the other of the silicon layer and the silicon germanium layer on the one.

In one implementation of the second aspect, the silicon germanium layer includes one selected from a group consisting of compounds respectively represented by following Chemical Formulas 1 to 3:

Si_{1-x-y}GeₓB_{y} (0<x≤0.4, 0<y≤0.4) [Chemical Formula 1]

Si_{1-x-y-z}GeₓB_{y}P_{z} (0<x≤0.4, 0<y≤0.4, 0<z<0.4) [Chemical Formula 2]

Si_{1-x-y}GeₓP_{y} (0<x≤0.4, 0<y≤0.4). [Chemical Formula 3]

In one implementation of the second aspect, the silicon germanium layer is formed by supplying a boron (B) source gas or a phosphorus (P) source gas together with a silicon (Si) source gas and a germanium (Ge) source gas into a chamber at a temperature of 400 to 700° C. in which the substrate is disposed, such that boron (B) or the phosphorus (P) together with silicon (Si) and germanium (Ge) is deposited on the substrate or the silicon layer.

In one implementation of the second aspect, each of the silicon layer and the silicon germanium layer has an average thickness in a range of 0 nm exclusive to 200 nm inclusive.

A third aspect of the present disclosure provides a method for manufacturing a semiconductor device, the method comprising: forming a stack on a substrate, wherein the forming of the stack includes performing a cycle composed of a first step and a second step a plurality of times to form the stack on the substrate, wherein the stack includes a plurality of silicon layers and a plurality of silicon germanium layers alternately stacked on top of each other, wherein the first step includes forming one of the silicon layer and the silicon germanium layer on the substrate, wherein the silicon germanium layer is doped with boron (B) or phosphorus (P), wherein the second step includes epitaxially forming the other of the silicon layer and the silicon germanium layer on the one; forming a first opening in the stack so as to expose a first side surface of each of at least one silicon layer and at least one silicon germanium layer; doping phosphorus (P) into the first side surface of the at least one silicon layer exposed through the first opening via a thermal diffusion process using a phosphorus (P) source gas, thereby forming a first electrode; forming a second opening so as to be spaced apart from the first opening and so as to expose a second side surface of each of the at least one silicon layer and the at least one silicon germanium layer; selectively etching the at least one silicon layer in the second opening so as to form a semiconductor pattern such that the first electrode is formed on a side surface of the semiconductor pattern; and doping phosphorus (P) into the side surface of the semiconductor pattern exposed through the second opening via a thermal diffusion process using a phosphorus (P) source gas, thereby forming a second electrode, wherein a portion of the silicon pattern located between the first electrode and the second electrode functions as a semiconductor channel.

In one implementation of the third aspect, the silicon germanium layer includes one selected from a group consisting of compounds respectively represented by following Chemical Formulas 1 to 3:

Si_{1-x-y}GeₓB_{y} (0<x≤0.4, 0<y≤0.4) [Chemical Formula 1]

Si_{1-x-y-z}GeₓB_{y}P_{z} (0<x<0.4, 0<y≤0.4, 0<z≤0.4) [Chemical Formula 2]

Si_{1-x-y}GeₓP_{y} (0<x≤0.4, 0<y≤0.4). [Chemical Formula 3]

In one implementation of the third aspect, the silicon layer is formed by supplying a silicon (Si) source gas into a chamber so as to deposit silicon on the substrate or the silicon germanium layer, wherein the silicon germanium layer is formed by supplying a silicon (Si) source gas, a germanium (Ge) source gas, and a boron (B) source gas into the chamber so as to deposit silicon (Si), germanium (Ge), and boron (B) on the substrate or the silicon layer, wherein during the formation of the silicon germanium layer, the silicon layer is doped with a smaller amount of boron than an amount thereof doped into the silicon germanium layer, so that the semiconductor channel is made of boron-doped silicon.

In one implementation of the third aspect, the silicon germanium layer includes the compound represented by the Chemical Formula 1, wherein in the Chemical Formula 1, a ratio (y/x) of y to x is in a range of 0.06 to 0.15.

In one implementation of the third aspect, the silicon layer is formed by supplying a silicon (Si) source gas into a chamber so as to deposit silicon on the substrate or the silicon germanium layer, wherein the silicon germanium layer is formed by supplying a silicon (Si) source gas, a germanium (Ge) source gas, a boron (B) source gas, and a phosphorus (P) source gas into the chamber so as to deposit silicon (Si), germanium (Ge), boron (B) and phosphorus (P) on the substrate or the silicon layer, wherein during the formation of the silicon germanium layer, the silicon layer is doped with a smaller amount of a combination of boron and phosphorus than an amount thereof doped into the silicon germanium layer, such that the semiconductor channel is made of silicon doped with boron and phosphorus.

In one implementation of the third aspect, the silicon germanium layer includes the compound represented by the Chemical Formula 2, wherein in the Chemical Formula 2, a ratio (y/x) of y to x is in a range of 0.06 to 0.15, and y is greater than or equal to z.

In one implementation of the third aspect, the silicon layer is formed by supplying a silicon (Si) source gas into a chamber so as to deposit silicon on the substrate or the silicon germanium layer, wherein the silicon germanium layer is formed by supplying a silicon (Si) source gas, a germanium (Ge) source gas, and a phosphorus (P) source gas into the chamber so as to deposit silicon (Si), germanium (Ge), and phosphorus (P) on the substrate or the silicon layer, wherein during the formation of the silicon germanium layer, the silicon layer is doped with a smaller amount of phosphorus than an amount thereof doped into the silicon germanium layer, such that the semiconductor channel is made of phosphorus-doped silicon.

In one implementation of the third aspect, the silicon germanium layer includes the compound represented by the Chemical Formula 3, wherein in the Chemical Formula 3, a ratio (y/x) of y to x is in a range of 0.06 to 0.15.

### Effects of the Invention

One of the several effects of the present disclosure is to reduce the difference between the lattice parameters of the Si layer and the Si—Ge layer.

One of the several effects of the present disclosure is that the stress between the Si layer and the Si—Ge layer can be relieved.

One of the several effects of the present disclosure is to be able to provide the epitaxial wafer and the method for manufacturing the epitaxial wafer in which the defects can be prevented from occurring.

One of the several effects of the present disclosure is to be able to provide the epitaxial wafer and the method for manufacturing the epitaxial wafer which can improve the integration of the semiconductor device.

In addition to the effects as described above, specific effects in accordance with the present disclosure will be described together with following detailed descriptions for carrying out the disclosure.

### BRIEF DESCRIPTION OF DRAWINGS

FIG. 1 is a perspective view schematically showing an epitaxial wafer according to an embodiment of the present disclosure.

FIG. 2 is a plan view of FIG. 1.

FIG. 3 is a cross-sectional view showing an I-I′ area of FIG. 1.

FIG. 4 is a cross-sectional view showing an II-II″ area of FIG. 1.

FIG. 5 is a graph showing a lattice parameter of each of (a) Si_{1-y}B_{y}, (b) Si_{1-y}Al_{y}, and (c) Si_{1-y}Ga_{y} as calculated using LDA and GGA-PBE.

FIG. 6 is a graph showing an average bond length based on a doping concentration of each of Si_{1-y}B_{y}, Si_{1-y}Al_{y} and Si_{1-y}Ga_{y}.

FIG. 7 is a graph showing a lattice parameter based on change in a concentration of each of Ge and B in Si_{1-x-y}GeₓB_{y}.

FIG. 8 is a schematic diagram for illustrating a mechanism based on which defects occur in the prior art.

FIG. 9 is a circuit diagram of a cell of a memory device according to an embodiment of the present disclosure.

FIG. 10 to FIG. 22 are process diagrams for illustrating a manufacturing process of the memory device.

### DETAILED DESCRIPTION FOR INVENTION'S IMPLEMENT

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may be actually executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Terms as used herein “first direction D1”, “second direction D2” and “third direction D3” should not be interpreted only to have a geometric relationship in which the first direction, the second direction, and the third direction are perpendicular to each other. The “first direction D1”, “second direction D2” and “third direction D3” may be interpreted to have a broader direction within a range in which components herein may work functionally.

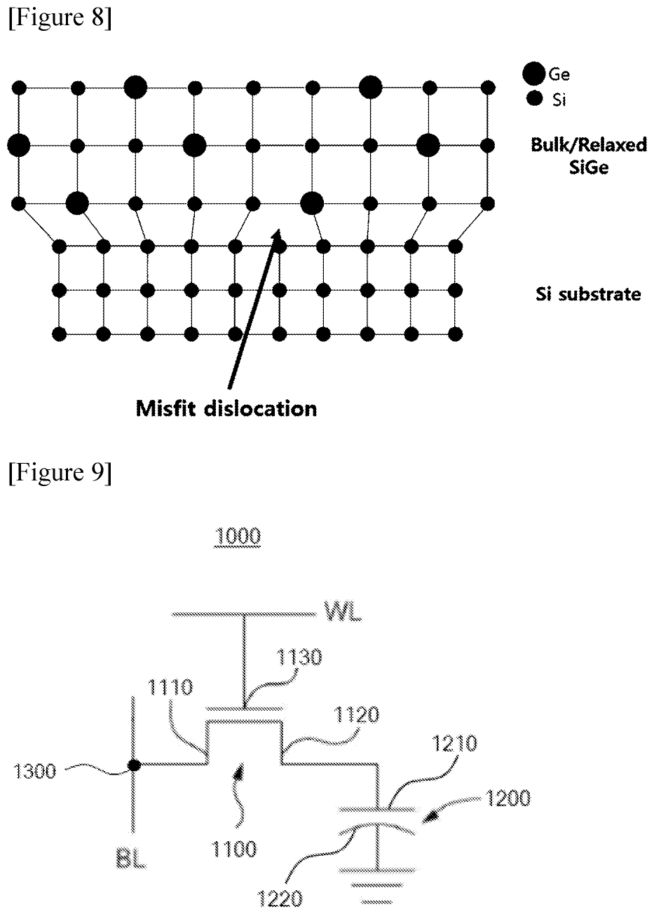

FIG. 8 is a schematic diagram to illustrate a mechanism based on which a defect occurs in a conventional wafer with a silicon layer and silicon germanium layer.

Referring to FIG. 8, when an epitaxial silicon layer and an epitaxial silicon germanium layer are stacked, defects inevitably occur therebetween due to a difference between lattice parameters of the silicon layer and the silicon germanium layer. Specifically, an atomic diameter of silicon is 5.43 Å, whereas an atomic diameter of germanium is 5.66 Å, and thus the silicon germanium layer has a larger lattice parameter than that of the silicon layer. Therefore, when epitaxially growing the silicon germanium layer on the silicon layer, a tensile stress is applied to the silicon layer due to the difference between the lattice parameters of the silicon germanium layer and the silicon layer. As a result, strain may occur, and misfit dislocation may occur at an interface therebetween. In particular, when a thickness of each of the silicon layer and the silicon germanium layer is small to improve the integration of the semiconductor device, the above problem may occur more frequently. Thus, a multilayer structure having a super large height cannot be implemented using the conventional wafer.

The present disclosure is designed to solve this problem. The inventors of the present disclosure have identified that when the silicon germanium (SiGe) layer is doped with boron (B) or phosphorus (P), the difference between the lattice parameters of the Si layer and the SiGe layer can be minimized, thereby minimizing interlayer defects in the multilayer structure having a super large height.

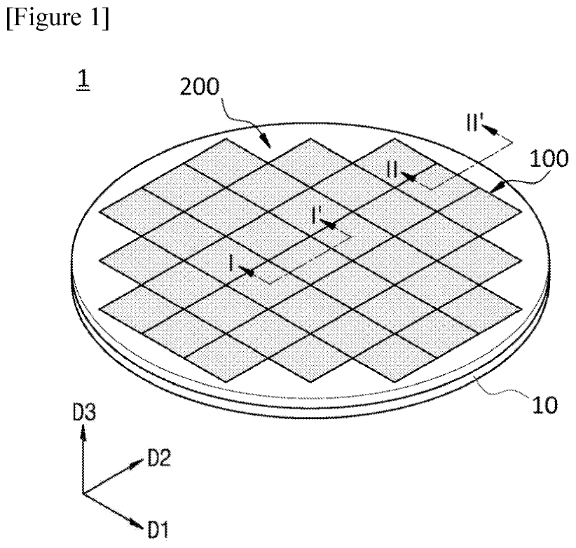

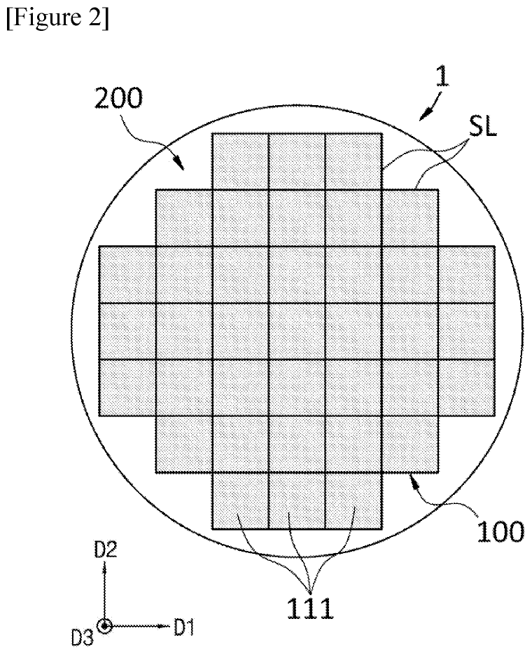

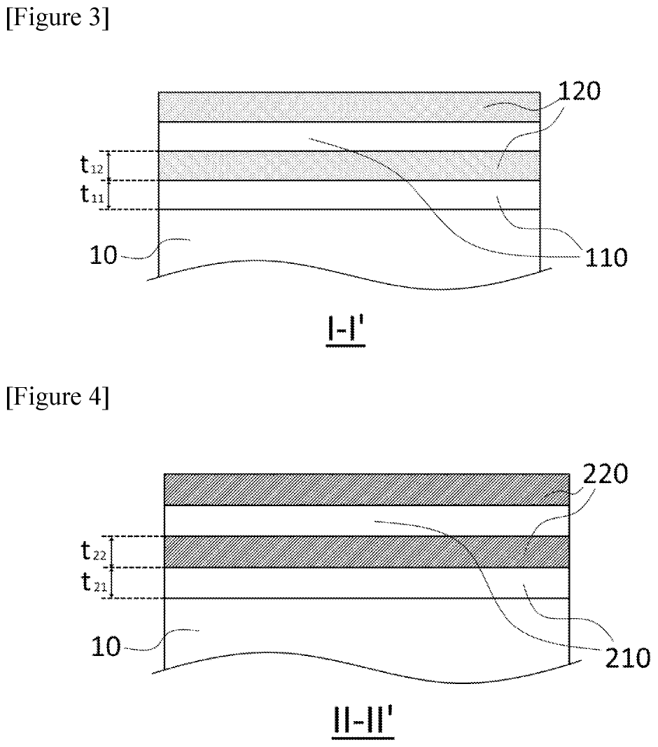

FIG. 1 is a perspective view schematically showing an epitaxial wafer according to an embodiment of the present disclosure. FIG. 2 is a plan view of the epitaxial wafer as shown in FIG. 1. FIG. 3 is a cross-sectional view schematically showing a first area 100 of an epitaxial wafer 1 according to the present disclosure, and FIG. 4 is a cross-sectional view showing an II-II″ area of FIG. 1.

Referring to FIG. 1 to FIG. 4, the epitaxial wafer 1 according to an embodiment of the present disclosure includes a substrate 10; and a first stack 210 and 220 disposed on the substrate 10.

The substrate 10 is not particularly limited, and a known substrate for a semiconductor device may be applied as the substrate 10 without limitation. In one embodiment, the substrate 10 may include a silicon wafer, wherein an insulating film is formed on a surface of the silicon wafer.

The first stack 210 and 220 may include silicon (Si) layers 210 and silicon germanium (SiGe) layers 220 alternately stacked on top of each other.

The silicon layer 210 may be made of single crystal silicon. In one embodiment, the silicon layer 210 may be formed using a chemical vapor deposition (CVD) scheme. For example, the silicon layer 210 may be formed on the substrate 10 by supplying a silicon (Si) source gas into a chamber having a temperature of about 400 to 700° C. in which the substrate 10 is disposed. In this regard, a known compound used in a semiconductor process may be applied as the silicon source gas without limitation. For example, neopentasilane (Si₅H₁₂), dichlorosilane (SiH₂Cl₂), and the like may be used as the silicon source gas.

The silicon germanium layer 220 defines an interface with the silicon layer 210, and may be doped with boron (B) or phosphorus (P). When the silicon germanium layer 220 is doped with boron (B) or phosphorus (P), the lattice parameter of the silicon germanium layer 220 may be reduced, and as a result, the difference between the lattice parameters of the silicon layer 210 and the silicon germanium layer 220 may be reduced. In one embodiment, the silicon germanium layer 220 may include at least one of compounds respectively represented by following Chemical Formulas 1 to 3:

Si_{1-x-y}GeₓB_{y} (0<x≤0.4, 0<y≤0.4) [Chemical Formula 1]

Si_{1-x-y-z}GeₓB_{y}P_{z} (0<x≤0.4, 0<y≤0.4, 0<z≤0.4) [Chemical Formula 2]

Si_{1-x-y}GeₓP_{y} (0<x≤0.4, 0<y≤0.4). [Chemical Formula 3]

In one embodiment, in each of the Chemical Formulas 1 to 3, a ratio (y/x) of y to x may be in a range of about 0.01 to 0.5, for example, in a range of about 0.06 to 0.15. Further, y may be greater than or equal to z.

In one embodiment, the silicon germanium layer 220 doped with boron (B) including the compound represented by the Chemical Formula 1 may be epitaxially formed on the substrate 10 or the silicon layer 210 using chemical vapor deposition (CVD). For example, the silicon (Si) source gas, the germanium (Ge) source gas, and the boron (B) source gas may be supplied into a chamber at a temperature of about 400 to 700° C. in which the substrate 10 on which the silicon layer 210 has been formed is disposed so as to deposit silicon (Si), germanium (Ge), and boron (B) on the silicon layer 210. Thus, the silicon germanium layer 220 doped with boron (B) including the compound represented by the Chemical Formula 1 may be formed. In this regard, known compounds applied to the semiconductor process may be used as the silicon source gas, the germanium source gas, and the boron source gas without limitation. For example, neopentasilane (Si₅H₁₂), dichlorosilane (SiH₂Cl₂), etc. may be used as the silicon source gas. Germane (GeH₄) or the like may be used as the germanium source gas, and diborane (B₂H₆) or the like may be used as the boron source gas. In one example, a composition of the compound represented by the Chemical Formula 1 may be controlled by adjusting a supply amount and a pressure of each of the source gases.

In one embodiment, the silicon germanium layer 220 doped with boron (B) and phosphorus (P) including the compound represented by the Chemical Formula 2 may be formed epitaxially on the substrate 10 or the silicon layer 210 using chemical vapor deposition (CVD). For example, the silicon (Si) source gas, the germanium (Ge) source gas, the boron (B) source gas, and a phosphorus (P) source gas may be supplied into a chamber at a temperature of about 400 to 700° C. in which the substrate 10 on which the silicon layer 210 has been formed is disposed so as to deposit silicon (Si), germanium (Ge), boron (B), and phosphorus (P) on the silicon layer 210. Thus, the silicon germanium layer 220 doped with boron (B) and phosphorus (P) including the compound represented by the Chemical Formula 2 may be formed. In this regard, known compounds applied to the semiconductor process may be used as the silicon source gas, the germanium source gas, the boron source gas, and the phosphorus source gas without limitation. For example, neopentasilane (Si₅H₁₂), dichlorosilane (SiH₂Cl₂), etc. may be used as the silicon source gas. Germane (GeH₄) or the like may be used as the germanium source gas, and diborane (B₂H₆) or the like may be used as the boron source gas. Phosphine (PH₃) or the like may be used as the phosphorus source gas. In one example, a composition of the compound represented by the Chemical Formula 2 may be controlled by adjusting a supply amount and a pressure of each of the source gases.

In one embodiment, the silicon germanium layer 220 doped with phosphorus (P) including the compound represented by the Chemical Formula 3 may be epitaxially formed on the substrate 10 or the silicon layer 210 using a chemical vapor deposition (CVD) scheme. For example, the silicon (Si) source gas, the germanium (Ge) source gas, and the phosphorus (P) source gas may be supplied into a chamber at a temperature of about 400 to 700° C. in which the substrate 10 on which the silicon layer 210 has been formed is disposed so as to deposit silicon (Si), germanium (Ge), and phosphorus (P) on the silicon layer 210. Thus, the silicon germanium layer 220 doped with phosphorus (P) including the compound represented by the Chemical Formula 3 may be formed. In this regard, known compounds applied to the semiconductor process may be used as the silicon source gas, the germanium source gas, and the phosphorus source gas without limitation. For example, neopentasilane (Si₅H₁₂), dichlorosilane (SiH₂Cl₂), etc. may be used as the silicon source gas. Germane (GeH₄) or the like may be used as the germanium source gas. Phosphine (PH₃) or the like may be used as the phosphorus source gas. In one example, a composition of the compound represented by the Chemical Formula 3 may be controlled by adjusting a supply amount and a pressure of each of the source gases.

In one embodiment, a thickness of each of the silicon (Si) layer and the silicon germanium (SiGe) layer may not be particularly limited. In one embodiment, each of an average thickness t₂₁ of the silicon (Si) layer and an average thickness t₂₂ of the silicon germanium (SiGe) layer may be about 200 nm or smaller, for example, in a range of about 5 to 100 nm.

In one embodiment, the first stack 210 and 220 may include about 2 to 1000 silicon layers 210 and about 2 to 1000 silicon germanium layers 220.

In one embodiment, the first stack 210 and 220 may be disposed on a second area 200 of an upper surface of the substrate 10, while a second stack for the semiconductor device may be disposed on a first area 100 of the upper surface of the substrate 10 surrounded with the second area 200.

In one embodiment, the second stack may include silicon (Si) layers 110 and insulating layers 120 alternately stacked on top of each other. For example, the silicon layer 110 of the second stack and the silicon layer 210 of the first stack may be formed as a remaining silicon layer in the silicon layers and the silicon germanium layers alternately stacked on top of each other and disposed on an entire area of the surface of the substrate 10. The silicon germanium layer 220 of the first stack may be formed as a remaining silicon germanium layer in the silicon layers and the silicon germanium layers alternately stacked on top of each other and disposed on an entire area of the surface of the substrate 10. The insulating layer 120 may be formed via selective removal of the silicon germanium layer on the first area in the silicon layers and the silicon germanium layers alternately stacked on top of each other and disposed on an entire area of the surface of the substrate 10.

In one embodiment, the insulating layer 120 may include an empty space. The insulating layer 120 may be used in a process of manufacturing the semiconductor device. More specifically, the insulating layer 120 may be formed by forming a mask pattern having an etch selectivity on the second area and etching at least a portion on the first area a plurality of times, or may be embodied as a space remaining after etching and removing the silicon germanium layer on the first area.

In one embodiment, the insulating layer 120 may be made of an insulating material including a different component from the silicon germanium layer on the second area. For example, the insulating layer 120 may be made of silicon oxide, silicon nitride, or silicon oxynitride. The insulating layer 120 may be formed by filling the aforementioned empty space with the insulating material.

In one embodiment of the present disclosure, a plurality of semiconductor unit semiconductor devices manufactured using the second stack may be disposed on the second area of the substrate 10. In this regard, the plurality of unit semiconductor devices may be arranged so as to be spaced apart from each other via a scribe line. In this case, as shown in FIG. 2, the first area 100 of the epitaxial wafer 1 may include a plurality of unit semiconductor devices 111 distinguished from each other the scribe line SL. The unit semiconductor devices may be cut and separated into individual chips via the scribe line SL in a wafer dicing process.

The scribe line SL may be formed in a grid pattern. For example, the scribe line SL may include a horizontal line extending along the first direction D1 and a vertical line extending along the second direction D2 intersecting the first direction D1. In FIG. 2, it is illustrated that a length in the first direction D1 of the unit semiconductor device and a length in the second direction D2 of the unit semiconductor device are the same as each other. However, the length in the first direction and the length in the second direction of the unit semiconductor device may be set to be different from each other as necessary.

In one embodiment of the present disclosure, each of the plurality of unit semiconductor devices included in the first area of the epitaxial wafer 1 may include a cell area CELL including a memory cell array and a peripheral circuit area PERI to control the memory cell array.

In one embodiment, the unit semiconductor device included in the first area may include a plurality of word-lines, a plurality of memory cell transistors respectively connected to the word-lines, and a plurality of bit-lines respectively connected to the memory cell transistors. The unit semiconductor device may have a structure in which one memory cell transistor is disposed between one word-line and one bit-line. A gate of the memory cell transistor may be connected to the word-line, and a source of the memory cell transistor may be connected to the bit-line. Each memory cell may include a capacitor. The word-line, the memory cell transistor, the bit-line, and the capacitor may constitute one memory cell, and a plurality of memory cells may be included in one unit semiconductor device.

In one embodiment of the present disclosure, at least two or more of the plurality of memory cell transistors included in each of the plurality of unit semiconductor devices disposed in the first area of the epitaxial wafer are stacked in a stacking direction of a stack structure. In this case, a plurality of memory cell transistors in a unit semiconductor device are stacked in the third direction D3. That is, the unit semiconductor device included in the first area of the epitaxial wafer according to the above example may be embodied as a 3D semiconductor memory device. The epitaxial wafer according to the present disclosure may have a structure in which the silicon layers and the boron-doped silicon germanium layers are alternately stacked on top of each other. As described above, the stress between the silicon layer and the silicon germanium layer may be reduced due to the boron-doped silicon germanium layer, thereby preventing interlayer dislocation from occurring. Thus, a memory device having a stack structure having a large vertical dimension in which the defects are suppressed can be implemented.

In one embodiment, the plurality of word-lines included in the unit semiconductor device manufactured from the epitaxial wafer 1 may extend in a direction perpendicular to the substrate. In one unit semiconductor device, the plurality of word-lines may be spaced apart from each other in the first direction D1 or the second direction D2. When the plurality of word-lines extend in a direction perpendicular to the substrate, the plurality of bit-lines included in the unit semiconductor device may extend horizontally (in a parallel manner with the substrate) and may be spaced apart from each other in the third direction D3.

In one embodiment, the plurality of bit-lines included in the unit semiconductor device of the epitaxial wafer 1 may extend in a direction perpendicular to the substrate. In one unit semiconductor device, the plurality of bit-lines may be spaced apart from each other in the first direction D1 or the second direction D2. When the plurality of bit-lines extend in a direction perpendicular to the substrate, the plurality of word-lines included in the unit semiconductor device may extend a horizontally (in a parallel manner with the substrate) and may be spaced apart from each other in the third direction D3.

In one embodiment, the plurality of word-lines and the plurality of bit-lines included in the unit semiconductor device manufactured from the epitaxial wafer 1 may extend in a direction perpendicular to the substrate. In one unit semiconductor device, the plurality of word-lines may be spaced apart from each other in the first direction D1 or the second direction D2 and the plurality of bit-lines may be spaced apart from each other in the first direction D1 or the second direction D2.

The word-line and/or the bit-line may be a conductive pattern and may have a line or bar shape. The word-line and/or the bit-line may include a conductive material. Examples of the conductive material may include one or more selected from a group consisting of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt, silicide, titanium silicide, etc.). However, the present disclosure is not limited thereto.

A method for manufacturing an epitaxial wafer according to an embodiment of the present disclosure includes alternately growing silicon layers and silicon germanium layers on to top of each other on a substrate, wherein the silicon germanium layer may be doped with boron (B) or phosphorus (P). The stack including the silicon layers and the silicon germanium layers alternately stacked on top of each other may be formed on the substrate by alternately growing the silicon layers and the silicon germanium layers on top of each other.

In one embodiment, the silicon layer 210 may be formed using a chemical vapor deposition (CVD) scheme. For example, the silicon layer 210 may be formed on the substrate 10 by supplying a silicon (Si) source gas into a chamber having a temperature of about 400 to 700° C. in which the substrate 10 is disposed. In this regard, a known compound applied to the semiconductor process may be used as the silicon source gas without limitation. For example, neopentasilane (Si₅H₁₂), dichlorosilane (SiH₂Cl₂), etc. may be used as the silicon source gas.

In one embodiment, the silicon germanium layer 220 may include at least one of compounds respectively represented by following Chemical Formulas 1 to 3:

Si_{1-x-y}GeₓB_{y} (0<x≤0.4, 0<y≤0.4) [Chemical Formula 1]

Si_{1-x-y-z}GeₓB_{y}P_{z} (0<x≤0.4, 0<y≤0.4, 0<z≤0.4) [Chemical Formula 2]

Si_{1-x-y}GeₓP_{y} (0<x≤0.4, 0<y≤0.4). [Chemical Formula 3]

In one embodiment, in each of the Chemical Formulas 1 to 3, a ratio (y/x) of y to x may be in a range of about 0.01 to 0.5, for example, in a range of about 0.06 to 0.15. Further, y may be greater than or equal to z.

In one embodiment, the silicon germanium layer 220 doped with boron (B) including the compound represented by the Chemical Formula 1 may be epitaxially formed on the substrate 10 or the silicon layer 210 using chemical vapor deposition (CVD). For example, the silicon (Si) source gas, the germanium (Ge) source gas, and the boron (B) source gas may be supplied into a chamber at a temperature of about 400 to 700° C. in which the substrate 10 on which the silicon layer 210 has been formed is disposed so as to deposit silicon (Si), germanium (Ge), and boron (B) on the silicon layer 210. Thus, the silicon germanium layer 220 doped with boron (B) including the compound represented by the Chemical Formula 1 may be formed. In this regard, known compounds applied to the semiconductor process may be used as the silicon source gas, the germanium source gas, and the boron source gas without limitation. For example, neopentasilane (Si₅H₁₂), dichlorosilane (SiH₂Cl₂), etc. may be used as the silicon source gas. Germane (GeH₄) or the like may be used as the germanium source gas, and diborane (B₂H₆) or the like may be used as the boron source gas. In one example, a composition of the compound represented by the Chemical Formula 1 may be controlled by adjusting a supply amount and a pressure of each of the source gases.

In one embodiment, the silicon germanium layer 220 doped with boron (B) and phosphorus (P) including the compound represented by the Chemical Formula 2 may be formed epitaxially on the substrate 10 or the silicon layer 210 using chemical vapor deposition (CVD). For example, the silicon (Si) source gas, the germanium (Ge) source gas, the boron (B) source gas, and a phosphorus (P) source gas may be supplied into a chamber at a temperature of about 400 to 700° C. in which the substrate 10 on which the silicon layer 210 has been formed is disposed so as to deposit silicon (Si), germanium (Ge), boron (B), and phosphorus (P) on the silicon layer 210. Thus, the silicon germanium layer 220 doped with boron (B) and phosphorus (P) including the compound represented by the Chemical Formula 2 may be formed. In this regard, known compounds applied to the semiconductor process may be used as the silicon source gas, the germanium source gas, the boron source gas, and the phosphorus source gas without limitation. For example, neopentasilane (Si₅H₁₂), dichlorosilane (SiH₂Cl₂), etc. may be used as the silicon source gas. Germane (GeH₄) or the like may be used as the germanium source gas, and diborane (B₂H₆) or the like may be used as the boron source gas. Phosphine (PH₃) or the like may be used as the phosphorus source gas. In one example, a composition of the compound represented by the Chemical Formula 2 may be controlled by adjusting a supply amount and a pressure of each of the source gases.

In one embodiment, the silicon germanium layer 220 doped with phosphorus (P) including the compound represented by the Chemical Formula 3 may be epitaxially formed on the substrate 10 or the silicon layer 210 using a chemical vapor deposition (CVD) scheme. For example, the silicon (Si) source gas, the germanium (Ge) source gas, and the phosphorus (P) source gas may be supplied into a chamber at a temperature of about 400 to 700° C. in which the substrate 10 on which the silicon layer 210 has been formed is disposed so as to deposit silicon (Si), germanium (Ge), and phosphorus (P) on the silicon layer 210. Thus, the silicon germanium layer 220 doped with phosphorus (P) including the compound represented by the Chemical Formula 3 may be formed. In this regard, known compounds applied to the semiconductor process may be used as the silicon source gas, the germanium source gas, and the phosphorus source gas without limitation. For example, neopentasilane (Si₅H₁₂), dichlorosilane (SiH₂Cl₂), etc. may be used as the silicon source gas. Germane (GeH₄) or the like may be used as the germanium source gas. Phosphine (PH₃) or the like may be used as the phosphorus source gas. In one example, a composition of the compound represented by the Chemical Formula 3 may be controlled by adjusting a supply amount and a pressure of each of the source gases.

In one example, the epitaxial wafer may further include an additional insulating film disposed on the uppermost silicon layer or silicon germanium layer as needed.

In one embodiment, a stack structure in which the silicon layers and the silicon germanium layers are alternately stacked on top of each other may be formed on the substrate 10, and then a patterning process may be performed thereon. The patterning process may include forming a mask pattern having openings defined therein, etching the stack structure using the mask pattern as an etching mask, and removing the mask pattern. Trenches may be formed on the substrate 10 using the patterning process, and a portion of the upper surface of the substrate may be exposed through the trenches. Thereafter, a process of forming a new insulating film inside the trench may be performed. The new insulating film may have etch selectivity.

The patterning process may be performed a plurality of times depending on a target structure of a semiconductor device. When the patterning process is performed a plurality of times, a process of etching at least a portion of the insulating film formed in a previous step and then forming a new insulating film may be performed. According to the present disclosure, after performing the patterning process, a semiconductor unit semiconductor device may be formed in the first area of the epitaxial wafer. The semiconductor unit semiconductor device may include a stack structure in which the silicon layers not removed in the patterning process and the insulating films newly formed after the silicon germanium layers has been removed via the etching are stacked on top of each other.

In one example, in the patterning process, a portion of the stack structure located on the second area of the substrate may be located outside the mask pattern and may not be patterned but may remain.

In one embodiment, after performing the patterning process, an impurity doping process may be performed onto a portion of the semiconductor as exposed via the etching, if necessary. The impurity may be a p-type impurity or an n-type impurity. The p-type impurities may include B, BF, or a combination thereof, and the n-type impurities may include P, As, or a combination thereof

In one embodiment, after performing the patterning process, a process of substituting the portion of the semiconductor exposed via the etching with a conductive material may be performed as needed. The process of replacing the portion of the semiconductor with the conductive material may include, for example, a silicide process. The exposed portion of the semiconductor may react with a metal to form a metal-semiconductor compound (tungsten silicide, cobalt silicide, titanium silicide, etc.). In another example, substituting the semiconductor with the conductive material may include conformally forming a metal nitride film or a metal film on the semiconductor.

In one embodiment, after performing the patterning process, a process of filling an insulating film in an empty space of each of the remaining trenches may be performed, if necessary. The insulating film may include one of a silicon oxide film, a silicon nitride film, and a silicon oxynitride film.

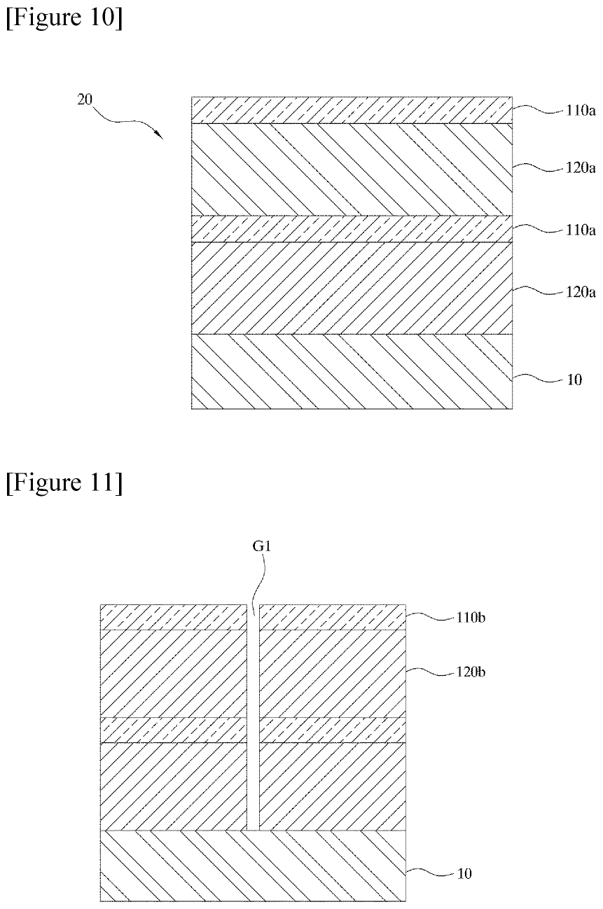

FIG. 9 is a circuit diagram of a memory cell of a memory device according to an embodiment of the present disclosure, and FIGS. 10 to 22 are process diagrams for illustrating a manufacturing process of the memory device.

Referring to FIG. 9, a memory cell 1000 of a memory device according to an embodiment of the present disclosure may include an n-type transistor 1100 and a capacitor 1200.

The n-type transistor 1100 may include a drain electrode 1110 electrically connected to a bit-line BL, a source electrode 1120 electrically connected to the capacitor 1200, a channel area formed between the drain electrode 1110 and the source electrode 1120, and a gate electrode 1130 electrically connected to a word-line WL.

In one embodiment, each of the source electrode 11200 and the drain electrode 1110 may be made of n type impurity-doped silicon, and the channel area may be made of p type impurity-doped silicon.

In one embodiment, the gate electrode 1130 may be disposed above the channel area, and a gate insulating layer may be disposed between the gate electrode 12 and the channel area. The gate electrode 1130 may be made of an electrically conductive material, for example, a metal or a metal-containing material, and the gate insulating film may be made of an insulating dielectric material.

The capacitor 1200 may include an outer electrode layer 1210 electrically connected to the source electrode 1120, an inner electrode layer 1220 electrically connected to a power supply node such as a ground node, and a dielectric layer disposed therebetween.

In one embodiment, each of the outer electrode layer 1210 and the inner electrode layer 1220 may be made of an electrically conductive material, such as a metal or a metal-containing material. The dielectric layer may be made of a high-k dielectric material.

Referring to FIG. 10 to FIG. 22, the method of manufacturing the memory device according to an embodiment of the present disclosure may manufacture a pair of mirrored memory device cells mirrored around a vertical axis. Although the drawing shows a process for manufacturing a pair of memory cells, the present disclosure is not limited thereto. When the number of the silicon layers and silicon germanium layers alternately stacked on top of each other is increased, a plurality of pairs of memory cells arranged in a deposition direction may be manufactured.

Referring to FIG. 10, a stack 20 of the silicon layers 110a and the silicon germanium layers 120a may be formed by stacking the silicon layers 110a and the silicon germanium layers 120a on top of each other on the substrate 10. The stack 20 may have a structure in which two or more silicon layers 110a and two or more silicon germanium layers 120a are alternately stacked on top of each other.

In one embodiment, each of the silicon layer 110a and the silicon germanium layer 120a may be formed using chemical vapor deposition in the same chamber. The silicon germanium layer 120a may be doped with boron (B) or may be doped with both boron (B) and phosphorus (P). In this case, during a process of forming the silicon germanium layer 120a, the silicon layer 110a may be doped with a trace amount of boron or phosphorus. A method for forming each of the silicon layer 110a and the silicon germanium layer 120a has already been described above. Thus, detailed redundant description thereof will be omitted.

Referring to FIG. 11, a first opening G1 extending through the silicon layers 110b and the silicon germanium layers 120b of the stack 20 may be formed. The first opening G1 may be formed using an anisotropic etching process such as reactive ion etching (RIE).

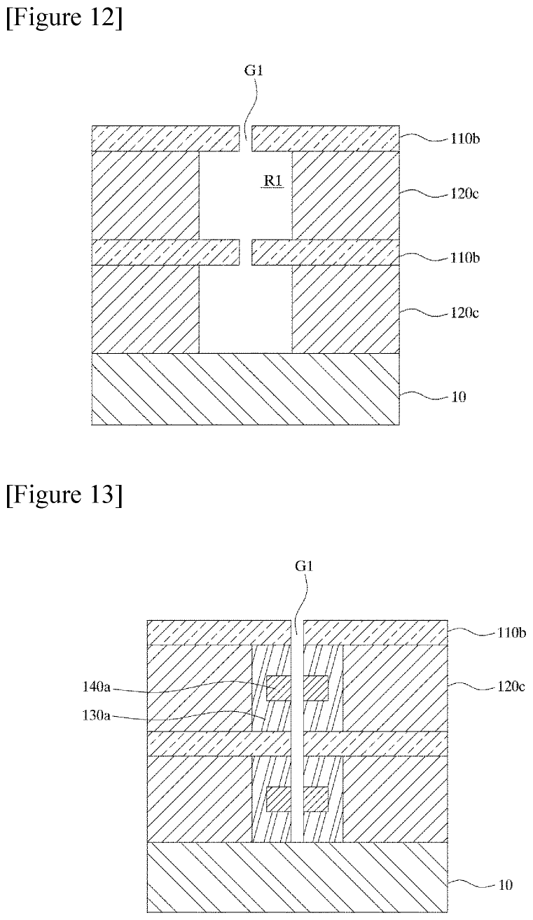

Referring to FIG. 12, a pullback process may be performed on silicon germanium layers 120c exposed through the first opening G1 such that each of first recesses R1 extending horizontally may be formed in each of the silicon germanium layers 120c. The pullback process may be performed via a selective and isotropic etching process on the silicon germanium layers 120c. For example, the pullback process on the silicon germanium layers 120c may be performed based on an etching process using a mixed solution of hydrogen fluoride (HF), hydrogen peroxide (H₂O₂) and acetic acid (CH₃COOH).

Referring to FIG. 13, an isotropic sacrificial material layer 130a and a dielectric filling material layer 140a may be formed in each of the first recesses R1 defined in each of the silicon germanium layers 120c. The isotropic sacrificial material 130a may be formed using an isotropic deposition process such as an atomic layer deposition (ALD) process. In this regard, the isotropic sacrificial material layer 130a of a constant thickness may be formed along the surfaces of the adjacent silicon layers 110b and a side surface of the pulled-back silicon germanium layer 120c located therebetween. A groove corresponding to the first recess R1 of the pulled-back silicon germanium layer 120c may be formed in a middle portion of the isotropic sacrificial material layer 130a. The dielectric filling material layer 140a may also be formed to fill the groove formed in the middle portion of the isotropic sacrificial material layer 130a using an isotropic deposition process.

In one embodiment, the isotropic sacrificial material layer 130a may be made of any material (for example, silicon nitride) having etch selectivity with respect to a material of each of the silicon layer 110b and the dielectric filling material layer 140a. The dielectric filling material layer 140a may be made of any material (for example, silicon oxide) having etching selectivity with respect to a material of each of the silicon layer 110b and the isotropic sacrificial material layer 130a.

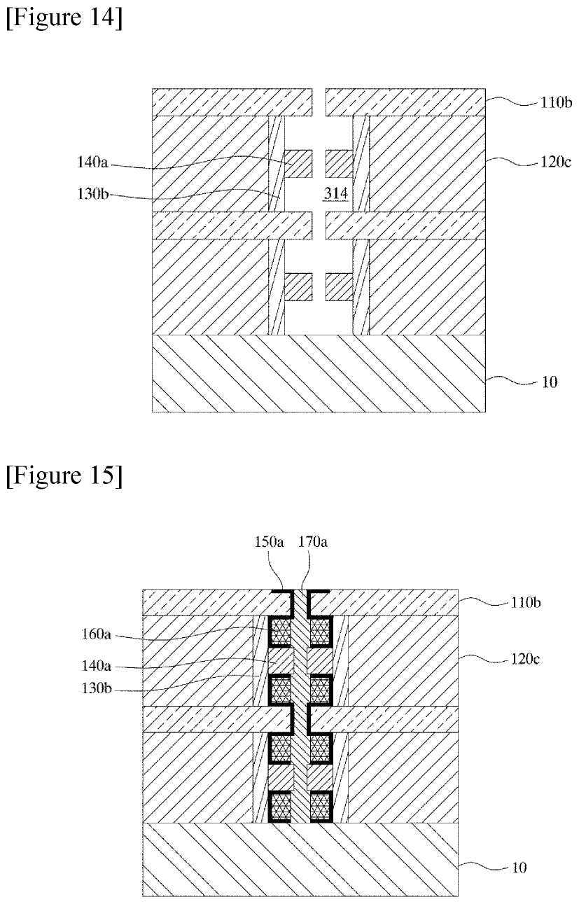

Referring to FIG. 14, a pullback process may be performed on the isotropic sacrificial material layers 130a exposed through the first opening R1 so that the dielectric filling material layer 140a protrudes from the isotropic sacrificial material layer 130a. In this regard, the pullback process may be performed so that a portion of the isotropic sacrificial material layer 130b remains on a side surface of the silicon germanium layer 120c. Accordingly, two grooves spaced from each other via the protruding dielectric filling material layer 140a may be formed on the side surface of the silicon germanium layer 120c located between the adjacent silicon layers 110b.

Referring to FIG. 15, a gate insulating layer 150a and a gate electrode 160a may be sequentially formed inside the two grooves formed on the side surface of the silicon germanium layer 120c. The gate insulating layer 150a may be formed along surfaces of the grooves so as to have a constant thickness, that is, conformally such that a groove extending horizontally may be defined by the gate insulating layer 150a. The gate electrode 160a may be formed to fill the groove. The gate insulating layer 150a may be made of a dielectric material such as silicon oxide, and the gate electrode 160a may be made of a metal material such as tungsten.

In one embodiment, after forming the gate insulating film 150a and the gate electrode 160a, a dielectric filling material 170a may fill the first opening G1 using a deposition process.

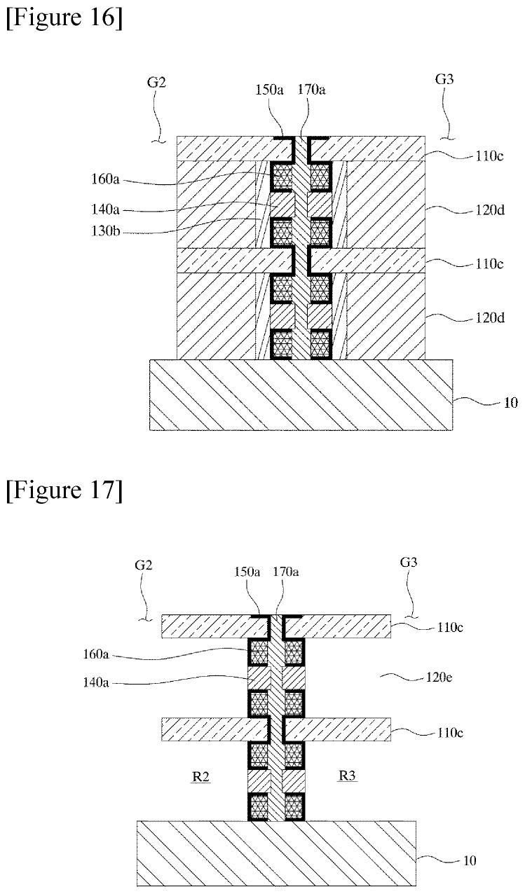

Referring to FIG. 16, a second opening G2 and a third opening G3 extending through the silicon layer 110c and the silicon germanium layer 120d of the stack 20 may be formed such that the second opening G2 and a third opening G3 are spaced apart from each other while the dielectric filling material 170a is disposed therebetween. The second and third openings G2 and G3 may be formed using an anisotropic etching process such as reactive ion etching (RIE).

Referring to FIG. 17, a pullback process may be performed on the silicon germanium layers 120d exposed through the second and third openings G2 and G3, such that a second recess R2 may be formed in the silicon germanium layer 120d so as to extend inwardly from a side surface of the second opening G2, and a third recess R3 may be formed in the silicon germanium layer 120d so as to extend inwardly from a side surface of the third opening G3. In this regard, a pullback process on the silicon germanium layer 120d may be performed to remove a residue portion of the isotropic sacrificial material layer 130b.

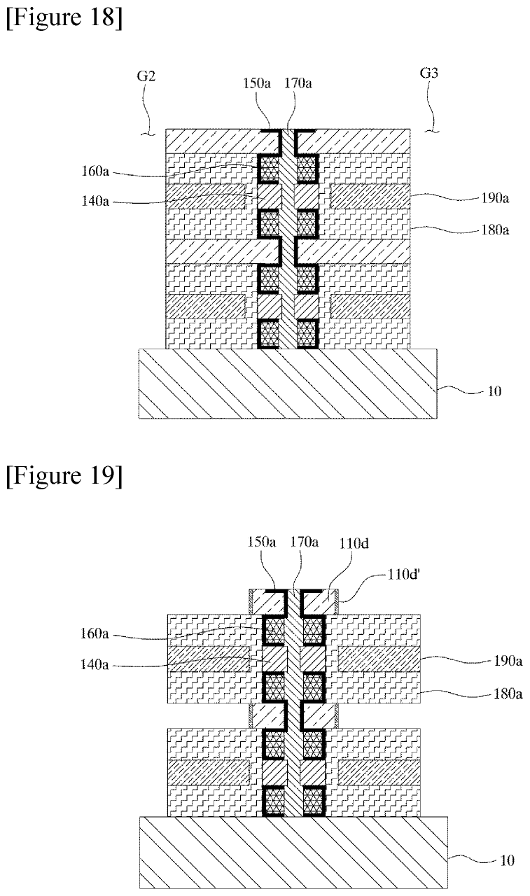

Referring to FIG. 18, a first dielectric material layer 180a and a second dielectric material layer 190a may be sequentially formed in each of the second recess R2 and the third recess R3. The first dielectric material layer 180a and the second dielectric material layer 190a may be respectively made of dielectric materials having etch selectivity with respect to each other and to the silicon layer 110c. The first dielectric material layer 180a may be formed using an isotropic deposition process such as an atomic layer deposition (ALD) process. In this regard, the first dielectric material layer 180a may be formed along surfaces of the adjacent silicon layers 110c and bottom faces of the second and third recesses R2 and R3 located therebetween so as to have a constant thickness, that is, conformally. As a result, a groove extending in a lateral direction or horizontally may be defined by the first dielectric material layer 180a. The second dielectric material layer 190a may be formed to fill the groove defined by the first dielectric material layer 180a using an isotropic deposition process.

Referring to FIG. 19, a pullback process may be performed on the silicon layer 110c exposed through the second opening G2 and the third opening G3 such that a portion thereof may remain. The pullback process on the silicon layer 110c may be performed based on an etching process using tetramethylammonium hydroxide (TMAH) or an isotropic dry plasma etching process.

After the pullback process has been completed, phosphorus (P) may be doped into a side surface of the remaining silicon layer 110d exposed through the second opening G2 and the third opening G3 to form a source electrode 110d′. Doping phosphorus (P) into the side surface of the residue silicon layer 110d may be performed based on a thermal diffusion process using a phosphorus (P) source gas. In one embodiment, phosphine (PH₃) or the like may be used as the phosphorus source gas.

In one embodiment, in a state in which a trace amount of boron and phosphorus has been doped into the silicon layer 110a in a process of forming the silicon germanium layer 120a doped with boron and phosphorus, the phosphorus may be doped into the residue silicon layer 110d via the thermal diffusion process using the phosphorus source gas, such that the source electrode 110d′ may be formed. In this case, a process time for forming the source electrode 110d′ using the thermal diffusion doping of phosphorus (P) may be significantly reduced.

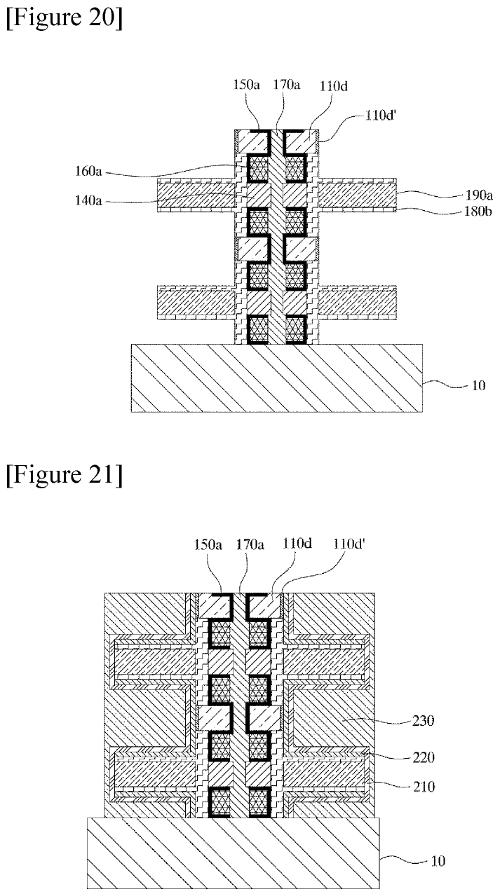

Referring to FIG. 20, a selective etching process may be performed on the first dielectric material layer 180a exposed thorough the second recess R2 and the third recess R3, such that a thickness of the first dielectric material layer 180a may be reduced. Accordingly, sizes of the second and third recesses R2 and R3 may be increased.

Referring to FIG. 21, an outer electrode layer 210, a dielectric layer 220, and an inner electrode layer 230 may be sequentially formed inside each of the second and third recesses R2 and R3. The outer electrode layer 210 and the inner electrode layer 230 may be formed using a deposition process of an electrically conductive material, and the dielectric layer 220 may be formed using a deposition process of a dielectric material. For example, the outer electrode layer 210 may be formed so as to have a constant thickness and may be formed along a surface of each of the second and third recesses R2 and R3 via an isotropic deposition process. The dielectric layer 220 may be formed along a surface of a groove defined by the outer electrode layer 210 corresponding to the second and the third recesses R2 and R3 and may have a constant thickness. The inner electrode layer 230 may be formed to fill a groove defined by the dielectric layer 220 corresponding to the second and third recesses R2 and R3. In this regard, the outer electrode layer 210 may be formed to be electrically connected to the source electrode 110d′.

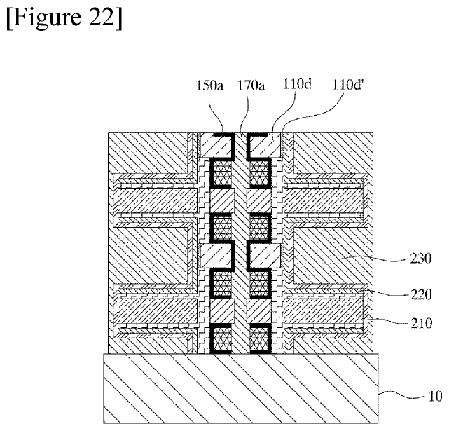

Referring to FIG. 22, the dielectric filling material 170a filling the first opening G1 may be etched to expose an end of the residue silicon layer 110d. Subsequently, a drain electrode 110d″ may be formed by n-doping the exposed end of the residue silicon layer 110d. Since the n-doping process for forming the drain electrode 110d″ is substantially the same as the n-doping process for forming the source electrode 110d″, repeated detailed description thereof will be omitted.

Next, an opening formed by etching the dielectric filling material 170a may be filled with a conductive material to form a bit-line node 300 for electrically connecting the drain electrode 110d″ to the bit-line BL.

The present disclosure will be described in more detail based on following Present Examples and Comparative Examples. However, the spirit of the present disclosure is not limited to Examples as described below.

Change in Each of Bond Length and Lattice Parameter of Silicon Due to Impurity Doping

The structure and elastic properties of silicon doped with boron were calculated based on a following method. First, a simulation on a supercell structure having 64 atoms was performed using DFT (density functional) to calculate a theoretical value. In the simulation scheme, the Vienna ab initio simulation package (VASP) tool was used to identify change in a bond length and a lattice parameter of silicon based on a varying concentration (0, 6.25, 12.5, and 18.75%) of dopants doped into a silicon layer. The simulation was conducted by setting a convergence value of a kinetic cutoff energy to 450 eV and calculating the theoretical value of the supercell with a 5×5×5 Monkhorst-Packgrid.

TABLE 1

| Material | atom % | Si—Si (Å) | Si—X (X = B, Al, Ga) (Å) |
|---|---|---|---|
| Si:B | 0 | 2.339 | n/a |

| | | | |
|---|---|---|---|
| 6.25 | 2.335 | 2.048 | (n: 16) |
| 12.5 | 2.336 | 2.028 | (n: 32) |
| 18.75 | 2.34 | 2.015 | (n: 48) |

| | | | |
|---|---|---|---|
| Si:Al | 0 | 2.339 | n/a |

| | | | |
|---|---|---|---|
| 6.25 | 2.343 | 2.426 | (n: 16) |
| 12.5 | 2.341 | 2.443 | (n: 32) |
| 18.75 | 2.339 | 2.45 | (n: 48) |

| | | | |
|---|---|---|---|
| Si:Ga | 0 | 2.339 | n/a |

| | | | |
|---|---|---|---|
| 6.25 | 2.341 | 2.378 | (n: 16) |
| 12.5 | 2.339 | 2.39 | (n: 32) |
| 18.75 | 2.337 | 2.397 | (n: 48) |

Table 1 shows the bond length based on the concentration when Si is doped with each of B, Al, and Ga belonging to group IIIA. As shown in Table 1, as a content of each doped element increases from 6.25 at % to 18.75 at %, the number of doping elements binding to Si increases from 0 to 48, and accordingly the number of Si—Si bonds decreases from 128 to 48 to 80.

Further, referring to Table 1, it may be identified that when the B atom is doped the bond length of Si—B decreases as the concentration of B increases. On the contrary, it may be identified that when the concentration of each of Al and Ga increases, the bond length of each of Si—Al and Si—Ga increases. Based on the above results, it may be identified that the bond length may be reduced when boron is doped into a crystal structure of Si.

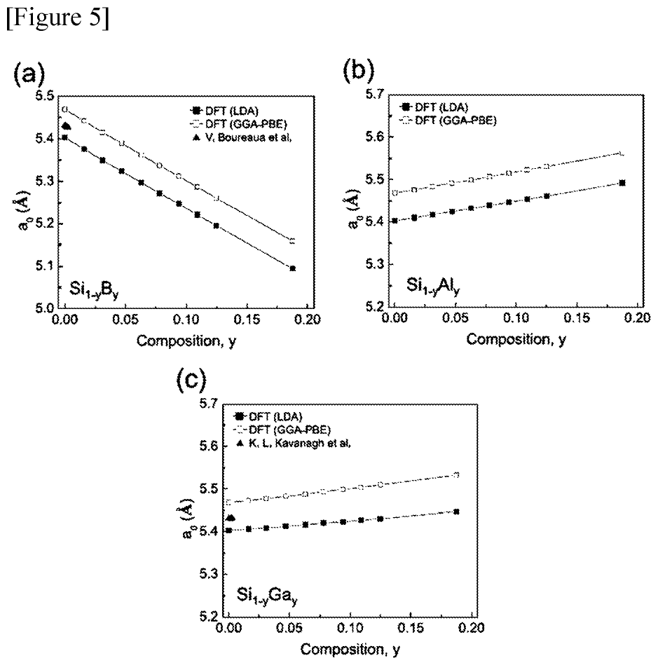

FIG. 5 shows a relaxed lattice parameter of each of (a) Si_{1-y}B_{y}, (b) Si_{1-y}Al_{y}, and (c) Si_{1-y}Ga_{y} calculated using LDA and GGA-PBE. Referring to FIG. 5, it may be identified that the relaxed lattice parameter decreases based on the increasing doping concentration of B belonging to the same group IIIA, while when each of Al and Ga belonging to the same group IIIA is doped, the relaxed lattice parameter increases as the doping concentration thereof increases.

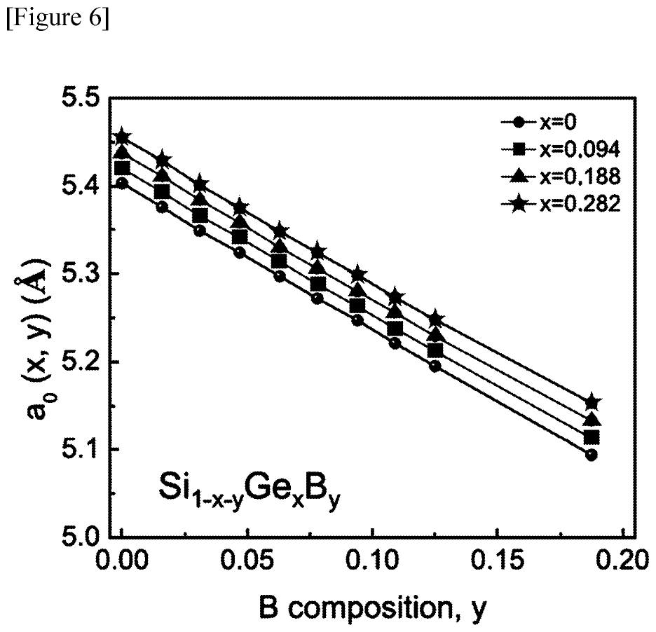

FIG. 6 is a graph showing an average bond length based on the doping concentration of each of Si_{1-y}B_{y}, Si_{1-y}Al_{y} and Si_{1-y}Ga_{y}. Referring to FIG. 6, as may be inferred from the change in the lattice parameter as described above, it may be identified that when B is doped, the average bond length decreases as the doping concentration thereof increases, whereas when each of Al and Ga is doped, the average bond length increases as the doping concentration thereof increases.

Effect of Doping on Silicon Germanium

Si and Ge have lattice parameters of 5.43 Å and 5.66 Å, respectively. In general, SiGe has a lattice parameter that changes between the above values and changes linearly in a proportional manner to a content of germanium included in a silicon layer. Therefore, when the silicon layer and the silicon germanium layer are sequentially epitaxially grown, the lattice parameter of the silicon germanium layer is greater than the lattice parameter of the silicon layer, such that a mismatch between the lattice parameter of the silicon layer and the lattice parameter of the silicon germanium layer may occur.

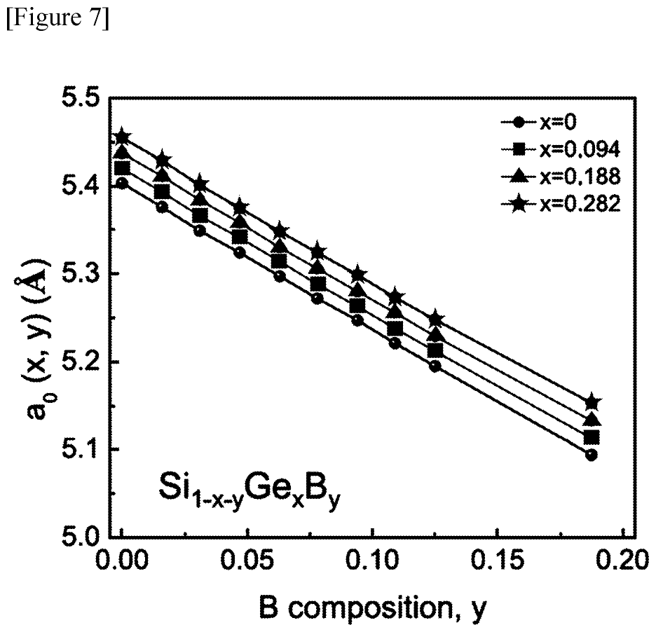

FIG. 7 is a graph displaying the lattice parameter calculated based on a varying concentration of B in Si_{1-x-y}GeₓB_{y}. x denotes a fraction of Ge, and y denotes a fraction of B. When y is 0, B represents the lattice parameter of undoped silicon germanium.

Referring to FIG. 7, it may be identified that the lattice parameter of Si_{1-x-y}GeₓB_{y} decreases as y increases. It may be identified that based on the change in a value of y, the lattice parameter of Si_{1-x-y}GeₓB_{y} may be controlled to 5.43 Å which is the lattice parameter of silicon. Further, it may be identified that even when the fraction of Ge increases, adjusting the fraction of B may allow the lattice parameter of Si_{1-x-y}GeₓB_{y} to be matched with that of silicon. Specifically, it may be identified that in Si_{1-x-y}GeₓB_{y}, the strain caused by germanium (Ge) doping at a 8.4 atomic % concentration may be cancelled by boron (B) doping at an about 1 atomic % concentration. Therefore, in the boron-doped silicon germanium layer, the ratio (y/x) of y to x is preferably in a range of about 0.06 to 0.15.

Based on the above results, it may be identified that when the silicon germanium layer contains boron, the difference between the lattice parameters of the silicon layer and the silicon germanium layer containing boron may be reduced. Therefore, the epitaxial wafer according to the present disclosure can minimize the difference between lattice parameters of the silicon layer and the silicon germanium layer, thereby minimizing the stress that may occur between the silicon layer and the silicon germanium layer. Thus, in a stack structure in which layers having different components are stacked on top of each other, occurrence of defects may be prevented by suppressing lattice parameter mismatch or dislocation between crystal lattice atoms.

Although the present disclosure has been described with reference to preferred embodiments of the present disclosure, those skilled in the art may modify and change the present disclosure variously without departing from the spirit and scope of the present disclosure as described in the Claims below.

1. An epitaxial wafer comprising:
a substrate; and
a stack disposed on the substrate, wherein the stack includes silicon (Si) layers and silicon germanium (SiGe) layers alternately stacked on top of each other,
wherein the silicon germanium layer is doped with boron (B) or phosphorus (P).

2. The epitaxial wafer of claim 1, wherein the silicon germanium layer includes one selected from a group consisting of compounds respectively represented by following Chemical Formulas 1 to 3:
Si_{1-x-y}GeₓB_{y} (0<x≤0.4, 0<y≤0.4) [Chemical Formula 1]
Si_{1-x-y-z}GeₓB_{y}P_{z} (0<x≤0.4, 0<y≤0.4, 0<z≤0.4) [Chemical Formula 2]
Si_{1-x-y}GeₓP_{y} (0<x≤0.4, 0<y≤0.4). [Chemical Formula 3]

3. The epitaxial wafer of claim 2, wherein the silicon germanium layer includes the compound represented by the Chemical Formula 1,
wherein in the Chemical Formula 1, a ratio (y/x) of y to xis in a range of 0.06 to 0.15.

4. The epitaxial wafer of claim 2, wherein the silicon germanium layer includes the compound represented by the Chemical Formula 2,
wherein in the Chemical Formula 2, a ratio (y/x) of y to x is in a range of 0.06 to 0.15, and y is greater than or equal to z.

5. The epitaxial wafer of claim 2, wherein the silicon germanium layer includes the compound represented by the Chemical Formula 3,
wherein in the Chemical Formula 3, a ratio (y/x) of y to x is in a range of 0.06 to 0.15.

6. The epitaxial wafer of claim 2, wherein an average thickness of each of the silicon layer and the silicon germanium layer is in a range of 0 nm exclusive to 200 nm inclusive.

7. A method for manufacturing an epitaxial wafer, the method comprising:
performing a cycle composed of a first step and a second step a plurality of times to form a stack on a substrate, wherein the stack includes a plurality of silicon layers and a plurality of silicon germanium layers alternately stacked on top of each other,
wherein the first step includes forming one of the silicon layer and the silicon germanium layer on the substrate, wherein the silicon germanium layer is doped with boron (B) or phosphorus (P),
wherein the second step includes epitaxially forming the other of the silicon layer and the silicon germanium layer on the one.

8. The method of claim 7, wherein the silicon germanium layer includes one selected from a group consisting of compounds respectively represented by following Chemical Formulas 1 to 3:
Si_{1-x-y}GeₓB_{y} (0<x≤0.4, 0<y≤0.4) [Chemical Formula 1]
Si_{1-x-y-z}GeₓB_{y}P_{z} (0<x≤0.4, 0<y≤0.4, 0<z≤0.4) [Chemical Formula 2]
Si_{1-x-y}GeₓP_{y} (0<x≤0.4, 0<y≤0.4). [Chemical Formula 3]

9. The method of claim 8, wherein the silicon germanium layer is formed by supplying a boron (B) source gas or a phosphorus (P) source gas together with a silicon (Si) source gas and a germanium (Ge) source gas into a chamber at a temperature of 400 to 700° C. in which the substrate is disposed, such that boron (B) or the phosphorus (P) together with silicon (Si) and germanium (Ge) is deposited on the substrate or the silicon layer.

10. The method of claim 9, wherein each of the silicon layer and the silicon germanium layer has an average thickness in a range of 0 nm exclusive to 200 nm inclusive.

11. A method for manufacturing a semiconductor device, the method comprising:
forming a stack on a substrate, wherein the forming of the stack includes performing a cycle composed of a first step and a second step a plurality of times to form the stack on the substrate, wherein the stack includes a plurality of silicon layers and a plurality of silicon germanium layers alternately stacked on top of each other, wherein the first step includes forming one of the silicon layer and the silicon germanium layer on the substrate, wherein the silicon germanium layer is doped with boron (B) or phosphorus (P), wherein the second step includes epitaxially forming the other of the silicon layer and the silicon germanium layer on the one;
forming a first opening in the stack so as to expose a first side surface of each of at least one silicon layer and at least one silicon germanium layer;
doping phosphorus (P) into the first side surface of the at least one silicon layer exposed through the first opening via a thermal diffusion process using a phosphorus (P) source gas, thereby forming a first electrode;
forming a second opening so as to be spaced apart from the first opening and so as to expose a second side surface of each of the at least one silicon layer and the at least one silicon germanium layer;
selectively etching the at least one silicon layer in the second opening so as to form a semiconductor pattern such that the first electrode is formed on a side surface of the semiconductor pattern; and
doping phosphorus (P) into the side surface of the semiconductor pattern exposed through the second opening via a thermal diffusion process using a phosphorus (P) source gas, thereby forming a second electrode,
wherein a portion of the silicon pattern located between the first electrode and the second electrode functions as a semiconductor channel.

12. The method of claim 11, wherein the silicon germanium layer includes one selected from a group consisting of compounds respectively represented by following Chemical Formulas 1 to 3:
Si_{1-x-y}GeₓB_{y} (0<x≤0.4, 0<y≤0.4) [Chemical Formula 1]
Si_{1-x-y-z}GeₓB_{y}P_{z} (0<x≤0.4, 0<y≤0.4, 0<z≤0.4) [Chemical Formula 2]
Si_{1-x-y}GeₓP_{y} (0<x≤0.4, 0<y≤0.4). [Chemical Formula 3]

13. The method of claim 12, wherein the silicon layer is formed by supplying a silicon (Si) source gas into a chamber so as to deposit silicon on the substrate or the silicon germanium layer,
wherein the silicon germanium layer is formed by supplying a silicon (Si) source gas, a germanium (Ge) source gas, and a boron (B) source gas into the chamber so as to deposit silicon (Si), germanium (Ge), and boron (B) on the substrate or the silicon layer,
wherein during the formation of the silicon germanium layer, the silicon layer is doped with a smaller amount of boron than an amount thereof doped into the silicon germanium layer, so that the semiconductor channel is made of boron-doped silicon.

14. The method of claim 13, wherein the silicon germanium layer includes the compound represented by the Chemical Formula 1,
wherein in the Chemical Formula 1, a ratio (y/x) of y to xis in a range of 0.06 to 0.15.

15. The method of claim 12, wherein the silicon layer is formed by supplying a silicon (Si) source gas into a chamber so as to deposit silicon on the substrate or the silicon germanium layer,
wherein the silicon germanium layer is formed by supplying a silicon (Si) source gas, a germanium (Ge) source gas, a boron (B) source gas, and a phosphorus (P) source gas into the chamber so as to deposit silicon (Si), germanium (Ge), boron (B) and phosphorus (P) on the substrate or the silicon layer,
wherein during the formation of the silicon germanium layer, the silicon layer is doped with a smaller amount of a combination of boron and phosphorus than an amount thereof doped into the silicon germanium layer, such that the semiconductor channel is made of silicon doped with boron and phosphorus.

16. The method of claim 15, wherein the silicon germanium layer includes the compound represented by the Chemical Formula 2,
wherein in the Chemical Formula 2, a ratio (y/x) of y to x is in a range of 0.06 to 0.15, and y is greater than or equal to z.

17. The method of claim 12, wherein the silicon layer is formed by supplying a silicon (Si) source gas into a chamber so as to deposit silicon on the substrate or the silicon germanium layer,
wherein the silicon germanium layer is formed by supplying a silicon (Si) source gas, a germanium (Ge) source gas, and a phosphorus (P) source gas into the chamber so as to deposit silicon (Si), germanium (Ge), and phosphorus (P) on the substrate or the silicon layer,
wherein during the formation of the silicon germanium layer, the silicon layer is doped with a smaller amount of phosphorus than an amount thereof doped into the silicon germanium layer, such that the semiconductor channel is made of phosphorus-doped silicon.

18. The method of claim 17, wherein the silicon germanium layer includes the compound represented by the Chemical Formula 3,
wherein in the Chemical Formula 3, a ratio (y/x) of y to xis in a range of 0.06 to 0.15.
